(19) United States
(12) Patent Application Publication
(10) Pub. No.: US 2004/0172812 A1
(43) Pub. Date: Sep. 9, 2004

(54) Device for displacing printed circuit boards

(76) Inventor: Arthur Robert Van Es, Eindhoven (NL)

Correspondence Address: US Philips Corporation, Intellectual Property Department, PO Box 3001, Briarcliff Manor, NY, 10510, US

(21) Appl. No.: 10/484,660

(22) PCT Filed: Jul. 29, 2002
(86) PCT No.: PCT/IB02/03202

(30) Foreign Application Priority Data
Jul. 31, 2001 (EP) 01202907.0

(51) Int. Cl. H05K 3/36

(52) U.S. Cl. 29/830

(57) ABSTRACT

The invention relates to a device for displacing PCBs (10) through a device wherein components can be mounted on the PCBs. The device comprises two beams (2) having regularly spaced teeth (3) for supporting the PCBs at opposite edges. Said beams can be moved up and down and displaced backwards and forwards in the longitudinal direction. Furthermore, two fixed supports (5) having teeth (6) are provided. The arrangement is such that to lift a PCB (10) resting on the supports (5), the teeth (3) of the beams (2) can be moved upwards in the spaces between the teeth (6) on the support members (5). For displacing the beams (2) in their longitudinal direction, the teeth (3) of the beams (2) can be arranged in a position below and a position above the teeth (6) of the support members (5).

The invention relates to a device for displacing printed circuit boards through a device in which components must be mounted on the printed circuit boards.

In known devices of the type mentioned above, the circuit boards are displaced using vertically movable pins whose upper ends are inserted into holes specially formed in the circuit board to carry a circuit board in a direction transverse to the longitudinal direction of the pins. In many applications, however, the provision of such holes in the circuit boards is unacceptable. In addition, separate clamping members must be provided to hold the circuit boards during the mounting of the components, which renders the device undesirably complicated and bulky.

In accordance with the invention, the device is provided with two parallel-arranged beams that can be displaced vertically and backwards and forwards in their longitudinal direction, which beams are equipped with regularly spaced teeth for supporting circuit boards at two opposite edges of the circuit boards, and the device is further provided with two fixedly arranged supports provided with teeth, the embodiment being such that for lifting a circuit board resting on the supports, the teeth of the beams can be moved upwards, in spaces between the teeth of the supports, while for displacing the beams backwards and forwards, the teeth of the beams can be arranged in a position below and a position above the teeth of the supports.

Using the construction in accordance with the invention, the circuit boards can be supported at their edges over an acceptable width by both the teeth of the beams and the teeth of the supports. Furthermore, the beams cannot only be used to displace the circuit boards through the device to mount the components, but also to press the circuit boards against a clamping beam, so that individual, complicated clamping mechanisms for securing the circuit boards during mounting the components can be dispensed with.

These and other aspects of the invention are apparent from and will be elucidated with reference to the embodiments described hereinafter.

In the drawings:

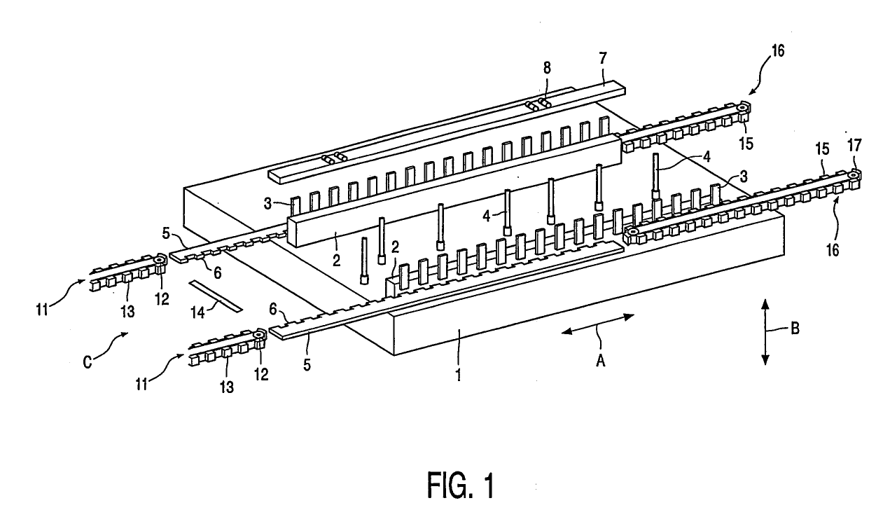

FIG. 1 is a diagrammatic, perspective view of a device in accordance with the invention.

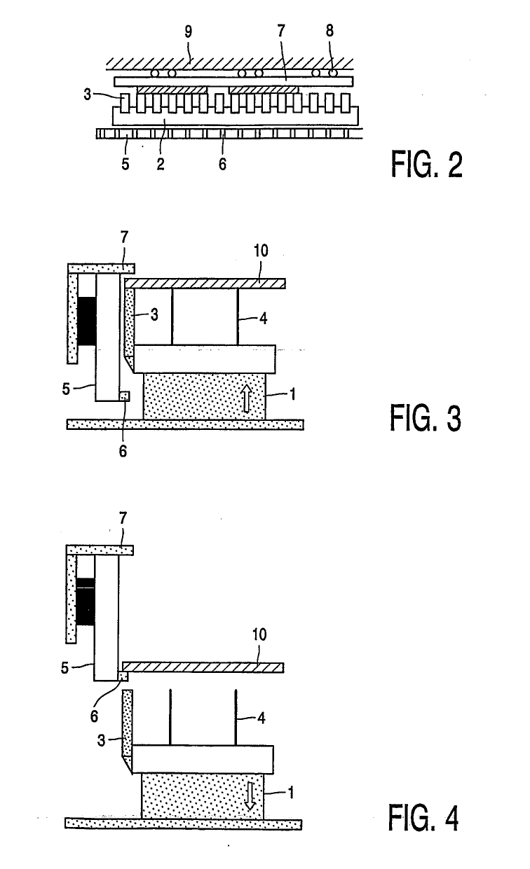

FIG. 2 is a diagrammatic side view of a detail of the device.

FIGS. 3 and 4 diagrammatically show the arrangement of a beam and a support in two positions relative to each other.

The device diagrammatically shown in the Figures comprises a carriage 1 which can be moved back and forth in the direction indicated by means of arrow A and up and down in the direction indicated by means of arrow B using drive mechanisms that are not shown in detail.

Said carriage is provided with two beams 2 that extend parallel to the displacement direction indicated by means of arrow A and are spaced some distance apart. Regularly spaced teeth 3 extending upwards are secured to the beams 2. Furthermore, pins 4 extending upwards can be arranged in desired patterns on the carriage.

In addition, the device is provided with two fixedly arranged supports 5 which are provided with projecting teeth 6 at the facing side faces.

Above one of the beams 2, a clamping beam 7 is arranged which extends parallel to the beams 2. This clamping beam 7 can preferably be reciprocated with the carriage 1 in the direction indicated by means of arrow A and, for this purpose, is supported, for example, by means of rollers 8 on a part 9 of the fixed frame of the device, which is not shown in more detail.

As is diagrammatically shown in, particularly, FIGS. 3 and 4, the arrangement is such that, viewed in the displacement direction of the carriage 1 as indicated by means of arrow A, the teeth 3 are situated, respectively, above and below the teeth 6, and upon displacing the carriage 1 upwards, as indicated by means of arrow B, the teeth of the beams 2 will move through the spaces between the teeth of the supports 5. It will be clear that this enables a circuit board 10 to be supported at two opposite side faces over an equal, narrow strip by the teeth 3 and the teeth 6, which would not be possible, for example, in an embodiment where, viewed in the displacement direction indicated by means of arrow A, the teeth 6 and 3 are juxtaposed. In said case, a much wider strip at the relevant opposite side edges of the circuit board 10 would have to be reserved for supporting the circuit board 10 during the various stages of displacing, depositing and/or processing the circuit board.

To feed the circuit boards to be processed in the direction indicated by means of arrow C, the device is equipped with two parallel-arranged conveyor belts 11 that are guided around tail pulleys 12 that can be rotated about vertical rotary shafts. Said conveyor belts are provided with regularly spaced, projecting teeth 13.

The facing teeth of the facing parts of the conveyor belts 11, which are driven in the direction indicated by means of arrow C to displace the circuit boards, support the circuit boards to be fed in a manner that is similar to the teeth 3 and 6, as shown in, respectively, FIG. 3 and FIG. 4.

At the area of the ends of the conveyor belts 11 close to the ends of the supports 5, a stop member 14 is provided by means of which a circuit board 10 conveyed on the conveyor belts 11 will be detained in a desired position so as to preclude further displacement by the conveyor belts in the direction indicated by means of arrow C.

To carry away the processed circuit boards, similar conveyor belts 16 having teeth 15 are provided in line with the supports 5 at the ends of the supports 5 facing away from the conveyor belts 11, said conveyor belts 16 being guided around tail pulleys 17 that can be rotated about vertical rotary shafts. Also these conveyor belts 16 can be driven such that the parts of the conveyor belts facing each other move in the direction indicated by means of arrow C.

To move the carriage 1 from the position shown in FIG. 1 in the direction of the conveyor belts 11, the carriage 1 and the toothed beam attached thereto is moved downwards into the position diagrammatically shown in FIG. 4, wherein the upper ends of the teeth 3 are in a lower position than the teeth 6.

Subsequently, the carriage 1 is moved into a position below the conveyor belts wherein a circuit board supported on the teeth 13 of the conveyor belts 11 and abutting against the stop 14 can be lifted by moving the table 1 upwards. To make this possible, a suitable drive of the conveyor belts 11 must make sure that the conveyor belts are detained in a position where the teeth 3 of the beams 2 can move upwards between the teeth 13 of the conveyor belts 11. The circuit board 10 thus lifted will rest on the upper ends of the teeth 3 as well as on the upper ends of the pins 4. In this operation, the table 1 is moved into a position wherein the circuit board is clamped between the upper ends of the teeth 3 and the clamping beam 7, and wherein the teeth 3 supporting the circuit board 10 are capable of moving along the upper side of the teeth 6. The circuit board thus lifted can consequently be displaced to the right by means of the carriage 1 shown in FIG. 1 until it is in a suitable position for mounting components.

After the desired components have been mounted on the circuit board, the table 1 can be lowered to the position diagrammatically shown in FIG. 4, wherein the relevant circuit board 10 comes to rest on the teeth 6, and possibly on the teeth 13. Subsequently, in the manner described above, a next circuit board can be picked up using the table 1. When a circuit board is lifted from the conveyor belts 11, also the circuit board 10 resting on the teeth 6 will be lifted and, during the subsequent displacement of the carriage 1, displaced to the right, viewed in FIG. 1, to a next station where possibly further components can be mounted on this circuit board 10, while the newly fed-in circuit board can be provided with components in the first station. In this manner, the circuit boards can be successively fed through one or more stations for mounting components, and eventually, after a downstroke of the table 1, they are placed by the teeth 3 on the teeth 15 of the out-feed conveyor belts 16.

Preferably, both the distance between the beams 2 and the distance between the supports 5 is adjustable so as to enable the device to be adapted to circuit boards of different width dimensions. Also the distance between the conveyor belts 11, 16 can be adapted.

Only five drives are necessary, i.e. one drive for the reciprocating movement of the carriage 1 in the direction indicated by means of arrow A, one drive for the vertical movement of the carriage 1 in the direction indicated by means of the arrow B, two drives for the conveyor belts 11 and 16, and one drive for adjusting the distance between the beams, the distance between the supports 5 and the distance between the conveyor belts 11, 16.

1. A device for displacing printed circuit boards (10) through a device in which components must be mounted on the printed circuit boards (10), characterized in that the device is provided with two parallel-arranged beams (2) that can be displaced vertically and backwards and forwards in the longitudinal direction, which beams are equipped with regularly spaced teeth (3) for supporting circuit boards (10) at two opposite edges of the circuit boards (10), and the device is further provided with two fixedly arranged supports (5) provided with teeth (6), the embodiment being such that for lifting a circuit board (10) resting on the supports, the teeth (3) of the beams (2) can be moved upwards, in spaces between the teeth (6) of the supports (5), while for displacing the beams (2) backwards and forwards, the teeth (3) of the beams (2) can be arranged in a position below and a position above the teeth (6) of the supports (5).

2. A device as claimed in claim 1, characterized in that the device for feeding circuit boards (10) is provided with two toothed conveyor belts (11), which are guided around guide members (12) that can be rotated about vertical rotary shafts, the conveyor belts (11) being arranged such that, viewed in the longitudinal direction of the conveyor belts (11), the teeth (13) of the conveyor belts (11) on the parts of the conveyor belts (11) facing each other are in line with the teeth (6) of the supports (5).

3. A device as claimed in claim 1 or 2, characterized in that at the area of the ends of the supports (5) facing away from the feed conveyor belts (11), discharge conveyor belts (16) are arranged that correspond to said feed conveyor belts (1).

4. A device as claimed in any one of the preceding claims, characterized in that above at least one of the beams (2), a clamping beam (7) is provided for clamping an edge of the circuit board (10) between the teeth (3) of the beam (2) in question and the clamping beam (7).

5. A device as claimed in claim 4, characterized in that the clamping beam (7) and the beams (2) provided with teeth (3) can be jointly reciprocated.

6. A device as claimed in any one of the preceding claims, characterized in that the distance between the beams (2) provided with teeth (3) and the distance between the supports (5) is adjustable.
